(19) United States
(12) Patent Application Publication
(10) Pub. No.: US 2007/0272282 A1
(43) Pub. Date: Nov. 29, 2007

(54) Composition for Removing Photoresist and Method for Removing Photoresist

(75) Inventors: Yoshitaka Nishijima, Hyogo (JP); Masatake Matsumoto, Hyogo (JP); Hidekuni Yasue, Hyogo (JP); Mizuki Takei, Hyogo (JP)

Correspondence Address: EDWARDS ANGELL PALMER & DODGE LLP, P.O. BOX 55874, BOSTON, MA, 02205, US

(73) Assignee: Nagase Chemtex Corporation, Osaka (JP)

(21) Appl. No.: 10/577,744

(22) PCT Filed: Oct. 28, 2004
(86) PCT No.: PCT/JP04/16012

§ 371 Date: Apr. 24, 2007

(30) Foreign Application Priority Data
Oct. 29, 2003 (JP) 2003-369349

(51) Int. Cl. G03F 7/42; H01L 21/027; H01L 21/304

(52) U.S. Cl. 134/42; 510/176

(57) ABSTRACT

Disclosed is a composition for removing a photoresist which contains a reaction product of a primary or secondary organic amine having a hydroxyl group with an ethylene carbonate, propylene carbonate, γ-butylolactone, 1,3-dihydroxy-2-propanone, or a monovalent or divalent carboxylic acid, if necessary an organic amine, and a water-soluble organic solvent and/or water. This composition is capable of removing a photoresist with high performance and preventing corrosion of a metal wiring material. By using such a composition, there occurs no problem such that impurities precipitate and adhere to the substrate or the like during water rinsing after removal.

### TECHNICAL FIELD

The present invention relates to a composition for removing a photoresist to be used in various fields such as production of semiconductor integrated circuits or semiconductor device circuits for liquid crystal display panels, and a method for removing a photoresist by the use of such a composition. More particularly, the present invention relates to a composition for removing a photoresist which is capable of exhibiting high performance in removing an unnecessary residual photoresist for forming wiring on a semiconductor substrate or a glass substrate for a liquid crystal display panel.

### BACKGROUND ART

Photoresists are typically used for forming semiconductor integrated circuits, semiconductor device circuits for liquid crystal display panels, and the like. Such photoresists are removed from substrates or the like using remover compositions. For example, a semiconductor device circuit or its associated electrode is formed in the following manner. A photoresist is evenly applied onto an insulating film such as a SiO₂ film or a metal film formed on a substrate such as a silicon substrate or a glass substrate by CVD or sputtering, and the photoresist is then subjected to exposure and development treatment to form a resist pattern. The metal or insulating film is selectively etched using a patterned photoresist as a mask. Thereafter, the photoresist layer that is no longer necessary is removed using a remover composition. These processes are repeatedly carried out to form a semiconductor device circuit or its associated electrode. Examples of the metal film described above include an aluminum (Al) film, aluminum alloy films such as an aluminum-silicon-copper (Al—Si—Cu) film, a titanium (Ti) film, titanium alloy films such as a titanium nitride (TiN) film, and silicon films such as an a-Si film and a p-Si film. These films can be formed on a substrate as a single layer or a multilayer structure of two or more of them.

Conventionally, a photoresist is removed using a remover composition obtained by dissolving any one, or two or more of compounds such as organic amine compounds, inorganic alkali compounds, organic acid compounds, and inorganic acid compounds in an organic solvent or water, and if necessary, adding an additive thereto. Examples of known photoresist remover liquids include a photoresist remover liquid containing an alkanolamine such as monoethanolamine (see, for example, Patent Literature 1 and 2), a photoresist remover liquid containing a pyrimidinone compound (see, for example, Patent Literature 3), and a photoresist remover liquid containing pyrocatechol and at least one nitrogen-containing organic hydroxy compound selected from N-hydroxyalkyl-substituted amines and nitrogen-containing heterocyclic hydroxy compounds (see, for example, Patent Literature 4).

However, when such a known photoresist remover liquid is used, it is necessary to carry out rinsing with an organic solvent such as an alcohol and/or water after removing a photoresist. In a case where it is necessary to carry out rinsing with water after rinsing with an organic solvent, there is a problem that the manufacturing process is complicated. On the other hand, in a case where a substrate is directly rinsed with water without carrying out rinsing with an organic solvent such as an alcohol, the manufacturing process is not complicated, but there is an other problem that insoluble matter is deposited during rinsing and is readhered to the substrate, which adversely affects device performance and reduces yield.
Patent Literature 1: Japanese Patent Laid-open No. Sho 62-49355
Patent Literature 2: Japanese Patent Laid-open No. Sho 63-208043
Patent Literature 3: Japanese Patent Laid-open No. 2000-171986
Patent Literature 4: Japanese Patent Laid-open No. Hei 11-258825

### DISCLOSURE OF THE INVENTION

### Problems to be Solved by the Invention

It is therefore an object of the present invention to provide a composition for removing a photoresist that is capable of exhibiting high performance in removing a photoresist, and that is also capable of properly preventing corrosion of a metal wiring material, and that does not cause a problem that insoluble matter is deposited during rinsing with water carried out after removing a photoresist and is readhered to a substrate or the like, and a method for removing a photoresist by the use of such a composition.

### Means to Solve the Problem

In order to achieve the object, the present inventors have intensively investigated, and as a result they have found that by using ethylene carbonate, propylene carbonate, 7-butyrolactone, 1,3-dihydroxy-2-propanone, or a carboxylic acid and a primary or secondary organic amine, it is possible to obtain a desired remover liquid. Based on the finding, the present inventors have further investigated, which has led to the completion of the present invention.

That is, one aspect of the present invention is a composition for removing a photoresist comprising at least one compound (A) selected from a group consisting of a compound represented by the following general formula (I), a compound represented by the following general formula (II), a compound represented by the following general formula (III), and a compound represented by the following general formula (IV):

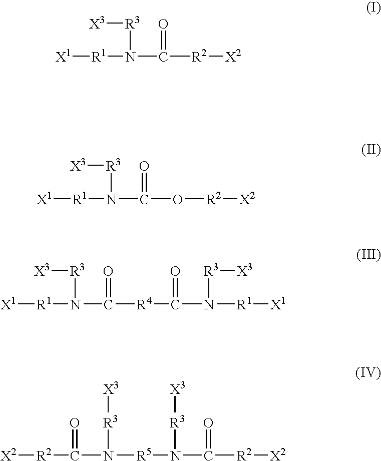

wherein formulas (I) to (IV), R¹ and R³ each independently represent a direct bond, or a linear or branched divalent hydrocarbon group having 1 to 5 carbon atoms, R² represents a linear or branched divalent hydrocarbon group having 1 to 5 carbon atoms, X¹, X², and X³ each independently represent a hydrogen atom, an OH group, or an alkyl group having 1 to 5 carbon atoms, and at least one of X¹, X², and X³ in each of the formulas (I) to (IV) is an OH group; wherein formulas (III) and (IV), the plurality of R¹s, R²s, and R³s, and the plurality of X¹s, X²s, and X³s are the same or different; wherein formula (III), R⁴ represents a direct bond, or a linear or branched divalent hydrocarbon group having 1 to 5 carbon atoms; and wherein formula (IV), R⁵ represents a divalent organic group.

In an embodiment of the present invention, the compound (A) is at least one compound selected from a group consisting of reaction products of ethylene carbonate and primary or secondary organic amines, reaction products of propylene carbonate and primary or secondary organic amines, reaction products of γ-butyrolactone and primary or secondary organic amines, reaction products of 1,3-dihydroxy-2-propanone and primary or secondary organic amines, and dehydration condensation reaction products of mono- or dicarboxylic acids and primary or secondary organic amines.

The composition of the present invention may further comprises an organic amine (B), a water-soluble organic solvent (C), or water (D), or two or more of them.

Another aspect of the present invention is a method for removing a photoresist, comprising the steps of:

(1) preparing the composition of the present invention; and

(2) immersing an object having a photoresist to be removed in the composition.

The method of the present invention may further comprises the step of rinsing the object with water in addition to the steps (1) and (2).

### EFFECTS OF THE INVENTION

(1) The composition of the present invention exhibits high performance in removing a residual photoresist. Therefore, by using the composition of the present invention, it is possible to remove a photoresist damaged during forming wiring in the manufacturing process of a device circuit for a semiconductor device or a liquid crystal panel without corrosion of a metal wiring material.

(2) The composition of the present invention has the effect of preventing corrosion of aluminum.

(3) The composition of the present invention does not cause a problem that insoluble matter is deposited during rinsing with water carried out after removing a photoresist and is readhered to an object to be treated such as a substrate.

### BEST MODE FOR CARRYING OUT THE INVENTION

A composition for removing photoresist according to the present invention (also simply referred to as a “composition of the present invention”) contains at least one compound (A) selected from a group consisting of a compound represented by the general formula (I), a compound represented by the general formula (II), a compound represented by the general formula (III), and a compound represented by the general formula (IV). In the general formulas (I) to (IV), R¹ and R³ each independently represent a direct bond, or a linear or branched divalent hydrocarbon group having 1 to 5 carbon atoms, and R² represents a linear or branched divalent hydrocarbon group having 1 to 5 carbon atoms. Examples of such a divalent hydrocarbon group having 1 to 5 carbon atoms include a methylene group, an ethylene group, a trimethylene group, a tetramethylene group, and a propylene group, and they may have a methyl group, an ethyl group, or the like as a branched chain. In the general formulas (I) to (IV), X¹, X², and X³ each independently represent a hydrogen atom, an OH group, or an alkyl group having 1 to 5 carbon atoms. Examples of such an alkyl group include a methyl group, an ethyl group, a propyl group, an isopropyl group, a butyl group, and an isobutyl group. It is to be noted that, in each of the general formulas, at least one of X¹, X², and X³ is an OH group, and that in the general formulas (III) and (IV), the plurality of R¹s, R²s and R³s, the plurality of X¹s, X²s X³s are the same or different, respectively. Further, in the general formula (III), R⁴ represents a direct bond, or a linear or branched divalent hydrocarbon group having 1 to 5 carbon atoms, and examples of such a divalent hydrocarbon group having 1 to 5 carbon atoms include the divalent hydrocarbon groups exemplified above. In the general formula (IV), R⁵ represents a divalent organic group, and examples of R⁵ include divalent hydrocarbon groups, groups represented by the formula, —R—NX—R— (where R represents an alkylene group and the plurality of Rs are the same or different, and X represents a hydrogen atom or a hydrocarbon group), and groups represented by the formula, —R—NX—R—NX—R— (where R represents an alkylene group, the plurality of Rs are the same or different, X represents a hydrogen atom or a hydrocarbon group, and the plurality of Xs are the same or different).

The compound (A) has an acid amide structure and at least one hydroxyl group.

In the compounds represented by the general formulas (I) to (IV), respectively, examples of X¹—R¹— include H—, HO—, HO—CH₂—, HO—CH₂CH₂—, HO—CH₂CH₂CH₂—, HO—CH(CH₃)CH₂—, CH₃—, CH₃CH₂—, CH₃CH₂CH₂—, CH₃CH(CH₃)—, CH₃CH₂CH₂CH₂—, and CH₃CH(CH₃)CH₂—, examples of X²—R²— include HO—CH₂—, HO—CH₂CH₂—, HO—CH₂CH₂CH₂—, HO—CH(CH₃)CH₂—, CH₃—, CH₃CH₂—, CH₃CH₂CH₂—, CH₃CH(CH₃)—, CH₃CH₂CH₂CH₂—, and CH₃CH(CH₃)CH₂—, and examples of X³—R³— include H—, HO—, HO—CH₂—, HO—CH₂CH₂—, HO—CH₂CH₂CH₂—, HO—CH(CH₃)CH₂—, CH₃—, CH₃CH₂—, CH₃CH₂CH₂—, CH₃CH(CH₃)—, CH₃CH₂CH₂CH₂—, and CH₃CH(CH₃)CH₂—.

Examples of the compound (A) include reaction products of ethylene carbonate and primary or secondary organic amines, reaction products of propylene carbonate and primary or secondary organic amines, reaction products of γ-butyrolactone and primary or secondary organic amines, reaction products of 1,3-dihydroxy-2-propanone and primary or secondary organic amines, and dehydration condensation reaction products of mono- or dicarboxylic acids and primary or secondary organic amines.

In the present invention, examples of a primary or secondary amine include alkyl amines such as triethylenetetramine and tetramethylethylenediamine; primary alkanolamines such as monoethanolamine (MEA), isopropanolamine, and diglycolamine (DGA); and secondary alkanolamines such as N-methylethanolamine, N-ethylethanolamine, N-butylethanolamine, and N, N-diethanolamine. These amines may be used singly or in combination of two or more of them.

Examples of a mono-carboxylic acid include acetic acid, propionic acid, butyric acid, and valeric acid. Examples of a dicarboxylic acid include oxalic acid, malonic acid, succinic acid, glutaric acid, and adipic acid. These carboxylic acids may be used singly or in combination of two or more of them.

Generally, reaction between ethylene carbonate, propylene carbonate, γ-butyrolactone, or 1,3-dihydroxy-2-propanone and a primary or secondary organic amine can be carried out under the conditions of 24 to 100° C. for 30 minutes to 1 hour. Proceeding of the reaction can be determined by checking consumption of starting materials or generation of reaction heat.

Reaction between propylene carbonate, γ-butyrolactone, or 1,3-dihydroxy-2-propanone and a primary or secondary organic amine involves nucleophilic attack of the amine on a carbonyl carbon to cleave an ether bond so that a bond, —N—C— is formed.

Dehydration condensation reaction between a mono- or dicarboxylic acid and a primary or secondary organic amine can be carried out under the conditions of 150 to 200° C. for 10 hours at a mole ratio of 2:1 to 1:4. If necessary, thionyl chloride or the like may be used. In a case where a dicarboxylic acid is used, at least one carboxyl group in its molecule is subjected to dehydration condensation reaction.

In the present invention, a specific example of the compound (A) may be at least one compound selected from a group consisting of bis(2-hydroxyethyl)carbamate, bis(2-hydroxypropyl)carbamate, N-(2-hydroxyethyl)-C-(3-hydroxypropyl)amide, N,N′-bis(2-hydroxyethyl)oxamide, N,N′-bis(2-hydroxyethyl)malonamide, (2-hydroxyethyl)acetamide, N-(2-hydroxyethyl)-N-methyl-C-(3-hydroxypropyl)amide, N-(2-hydroxyethyl)-N-ethyl-C-(3-hydroxypropyl)amide, and N,N-bis(2-hydroxyethyl)-C-(3-hydroxypropyl)amide.

The compound (A) contained in the composition of the present invention may be one previously prepared. Alternatively, the compound (A) may be prepared as a remover composition obtained by mixing ethylene carbonate, propylene carbonate, γ-butyrolactone, or 1,3-dihydroxy-2-propanone and a primary or secondary organic amine. In this case, ethylene carbonate, propylene carbonate, 7-butyrolactone, or 1,3-dihydroxy-2-propanone and a primary or secondary organic amine are mixed at a mole ratio of, for example, about 1 to 3:3 to 1. Preferably, amole ratio of primary or secondary organic amine/ethylene carbonate, propylene carbonate, γ-butyrolactone, or 1,3-dihydroxy-2-propanone is 1.0 or higher. Ethylene carbonate, propylene carbonate, γ-butyrolactone, or 1,3-dihydroxy-2-propanone and a primary or secondary organic amine can easily form a compound (A) even at room temperature, and therefore the composition containing them generally contains a compound (A) at room temperature. In such a case, the composition may contain unreacted raw materials of the compound (A) in addition to the compound (A).

As the compound (A) contained in the composition of the present invention, in the formulas (I) to (IV), one in which at least X¹ and X² are OH groups is preferred, and one in which X¹, X², and X³ are OH groups is more preferred, from the viewpoint of prevention of readhesion of a photoresist during washing with water.

If necessary, the composition of the present invention may further contain an organic amine (B), a water-soluble organic solvent (C), and water (D), or any one or two of them.

Examples of the organic amine (B) include alkylamines such as triethylenetetramine and tetramethylethylenediamine; primary alkanolamines such as monoethanolamine (MEA), isopropanolamine, and diglycolamine (DGA); secondary alkanolamines such as N-methylethanolamine, N-ethylethanolamine, N-butylethanolamine, and N,N-diethanolamine; tertiary alkanolamines such as N,N-dimethylethanolamine, N,N-diethylethanolamine, N,N-dibutylethanolamine, N-methyl-N,N-diethanolamine, and N,N-bis(2-hydroxyethyl)cyclohexylamine; and quaternary ammonium compounds such as tetramethylammonium hydroxide and trimethyl(2-hydroxyethyl)ammonium hydroxide, and they may be used singly or in combination of two or more of them. Among them, primary alkanolamines such as monoethanolamine, isopropanolamine, and diglycolamine are preferably used. The organic amine (B) may be the same as or different from an organic amine to be used as a raw material of the compound (A). As described above, in a case where the compound (A) is prepared as a remover composition obtained by mixing a primary or secondary organic amine and ethylene carbonate, propylene carbonate, γ-butyrolactone, or 1,3-dihydroxy-2-propanone, the organic amine (B) maybe added to the composition of the present invention by mixing them in such a manner that a mole ratio of primary or secondary organic amine/ethylene carbonate, propylene carbonate, γ-butyrolactone, or 1,3-dihydroxy-2-propanone becomes 1.0 or higher.

The amount of the compound (A) contained in the composition of the present invention is preferably 5 to 100 wt %, more preferably 10 to 70 wt %. If the amount of the compound (A) contained in the composition of the present invention is less than 5 wt %, there is a fear that the effect of preventing deposition of insoluble matter during rinsing with water carried out after removing a photoresist is low.

The amount of the organic amine (B) contained in the composition of the present invention is preferably 1 to 95 wt %, more preferably 5 to 90 wt %. If the amount of the organic amine contained in the composition of the present invention is less than 1 wt %, the effect of removing a residual photoresist tends to be low. On the other hand, if the amount of the organic amine contained in the composition of the present invention exceeds 95 wt %, there is a fear that the effect of preventing deposition of insoluble matter during rinsing with water carried out after removing a photoresist is low.

Examples of the water-soluble organic solvent (C) that may be contained in the composition of the present invention include diethylene glycol monomethyl ether, diethylene glycol monoethyl ether, diethylene glycol monopropyl ether, diethylene glycol monobutyl ether (BDG), N,N-dimethylacetamide (DMAC), N,N-dimethylformamide, N-methyl-2-pyrrolidone (NMP), ethylene carbonate (EC), propylene carbonate (PC), γ-butyrolactone (GBR), dimethyl sulfoxide (DMSO), ethylene glycol, and propylene glycol, and they may be used singly or in combination of two or more of them. It is to be noted that, as described above, in a case where the compound (A) is prepared as a reaction product in the composition, unreacted ethylene carbonate (EC), propylene carbonate (PC), or γ-butyrolactone (GBR) may be contained in the composition as the water-soluble organic solvent (C).

The amount of the water-soluble organic solvent (C) contained in the composition of the present invention is preferably 5 to 95 wt %, more preferably 10 to 90 wt %. If the amount of the water-soluble organic solvent contained in the composition of the present invention is less than 5 wt %, the effect of removing a residual photoresist tends to be low. On the other hand, if the amount of the water-soluble organic solvent contained in the composition of the present invention exceeds 95 wt %, there is a fear that the effect of preventing deposition of insoluble matter during rinsing with water carried out after removing a photoresist is low. It is to be noted that, as described above, in a case where the compound (A) is prepared as a reaction product in the composition, the total amount of unreacted ethylene carbonate (EC), propylene carbonate (PC), γ-butyrolactone (GBR) or the like and the water-soluble organic solvent is preferably within the above range.

The amount of the water (D) contained in the composition of the present invention is preferably 5 to 95 wt %, more preferably 5 to 60 wt %, even more preferably 5 to 40 wt %. If the amount of the water contained in the composition of the present invention is less than 5 wt %, it tends to be difficult to obtain the effect of removing a residual photoresist. On the other hand, if the amount of the water contained in the composition of the present invention exceeds 95 wt %, there is a fear that the effect of preventing deposition of insoluble matter during rinsing with water carried out after removing a photoresist is low.

The composition of the present invention may further contain an anti-corrosive for metals such as aluminum and copper in an amount of 0.1 to 10 wt %. Examples of such an anti-corrosive include 1,2,3-benzotriazole, 2-mercaptobenzoimidazole, 2,3-dihydroxynaphthalene, 2-mercaptoimidazole, D-sorbitol, benzoic acid, maltol, and Kojic acid.

The composition of the present invention can be manufactured by, for example, a method (1) in which all components are mixed at one time, or a method (2) in which the compound (A) is previously prepared and is then mixed with other components, or a method (3) in which ethylene carbonate, propylene carbonate, γ-butyrolactone, or 1,3-dihydroxy-2-propanone and a primary or secondary organic amine are previously mixed and then the mixture is mixed with other components. Among these methods, the method (2) or the method (3) is preferably employed.

A method for using the composition of the present invention will now be described by taking as an example, a case where a semiconductor device is manufactured using a glass substrate for a liquid crystal panel or a semiconductor substrate. The method typically comprises the steps of: (1) preparing a photoresist remover composition; and (2) immersing an object having a photoresist to be removed in the photoresist remover composition. If necessary, the method further comprises the step of rinsing the object with water after the step (2). Hereinbelow, an example of the method for using the composition of the present invention will be described in detail. A metal film such as an Al alloy film or an insulating film such as a SiO₂ film is formed on a substrate by, for example, CVD or sputtering. Then, a photoresist film is formed thereon, and a photomask is disposed on the photoresist film to carry out exposure and development treatment for patterning of the photoresist. The metal thin film is subjected to dry etching using a gas containing Cl₂ or CF₄ as a main ingredient while the patterned photoresist is used as an etching mask. Thereafter, the photoresist is subjected to ashing, and then a residual photoresist remaining on the substrate is removed using the composition of the present invention. More specifically, the substrate that has been subjected to ashing is immersed as an object to be treated in the composition of the present invention previously prepared so that a residual photoresist is removed from the substrate by dissolving it in the composition or by removing it from the substrate. At this time, the temperature and time for immersing the substrate in the composition of the present invention are usually 24 to 80° C. and 30 seconds to 30 minutes, respectively. In this way, a semiconductor device having wiring and the like on the surface thereof is manufactured.

Alternatively, the metal thin film may be subjected to wet-etching using an etchant containing cerium ammonium nitrate as a main ingredient while the patterned photoresist is used as an etching mask. Then, the substrate is immersed in the composition of the present invention so that a residual photoresist is removed from the substrate by dissolving it in the composition or by removing it from the substrate.

By using the composition of the present invention, it is possible to easily remove a residual photoresist from a substrate without corrosion of a metal film such as an Al alloy film formed on the substrate. Therefore, patterning on the substrate can be carried out with a high degree of precision. Generally, when a photoresist is removed using a remover liquid, a remover liquid is heated, or is showered or sprayed on a substrate, or is used together with ultrasonic wave if necessary, to improve the removing performance of the remover liquid. Therefore, also in a case where a photoresist is removed using the method of the present invention, such a method for improving removing performance can be used if necessary.

The composition of the present invention can be easily removed or washed off by rinsing with water after removing a photoresist. In the case of a conventional remover liquid, there is a problem that a photoresist is deposited as insoluble matter during rinsing and is again adhered to a substrate, thereby causing contamination of the substrate. However, the composition of the present invention does not cause such a problem, and therefore it is possible to manufacture semiconductor integrated circuits or semiconductor device circuits for liquid crystal panels with high yield.

The composition of the present invention exhibits good performance on any conventional photoresists, but exhibits especially good performance on positive photoresists containing a novolac resin and a naphthoquinone diazide compound.

Hereinbelow, the present invention will be described in more detail with reference to Examples and Comparative Examples. However, the present invention is not limited to these Examples.

1. Test for Removing Performance and Non-Corrosiveness

A Ti film was formed on a glass substrate, a TiN film was formed on the Ti film, and an Al film was formed on the TiN film. The glass substrate was subjected to dry-etching using Cl₂ and BCl₃ while a patterned photoresist (positive type) was used as a mask. Then, the surface of the photoresist was subjected to plasma ashing using oxygen and water. The photoresist damaged by ashing was removed in the following manner. The glass substrate was immersed in a removing composition, obtained by mixing components as shown in Table 1, at 80° C. for 1 minute. Then, pure water having a temperature of 24° C. was showered on the glass substrate for 1 minute, and finally the glass substrate was dried with nitrogen gas. The glass substrate was observed with a scanning electron microscope (SEM) to check the removing performance of the remover composition (that is, to check the absence or presence of a photoresist damaged by ashing) and to check the degree of corrosion of aluminum. The results are shown in Table 1. The removing performance was evaluated according to two criteria, and in Table 1, the mark “o” indicates that no photoresist was observed, and the mark “x” indicates that a residual photoresist was observed. The non-corrosiveness to aluminum was evaluated according to two criteria, and in Table 1, the mark “o” indicates that no corrosion was observed, and the mark “x” indicates that the width of the wiring was decreased or surface roughness was observed.

2. Test for Readhesion Property

In consideration of a case where a substrate is directly rinsed with water after removing a photoresist from the substrate, a test was carried out to determine whether or not insoluble matter was readhered to a substrate during rinsing with pure water. A 5-inch Si wafer was treated with 0.5% hydrofluoric acid at 24° C. for 30 seconds with a spinner to remove a native oxide film formed on the surface of the Si wafer. Then, pure water was showered on the Si wafer for rinsing while the Si wafer was rotated at 1,000 rpm for 15 seconds, and further rotated at 5,000 rpm for 8 seconds to remove the pure water from the surface of the Si wafer. A liquid obtained by dissolving 2 wt % of a photoresist solid (positive-type) in a remover composition obtained by mixing components as shown in Table 1 was dropped on the Si wafer, and was spread across the surface of the Si wafer while the Si wafer was rotated at 100 rpm for 10 seconds and was further rotated at 5,000 rpm for 10 seconds. Finally, pure water was showered on the Si wafer for rinsing while the Si wafer was rotated at 1,000 rpm for 15 seconds, and the Si wafer was further rotated at 5,000 rpm for 8 seconds to remove the pure water from the surface of the Si wafer. Thereafter, the number of particles having a particle diameter of 0.2 μm or more was counted with TOPCON WM-3 (manufactured by TOPCON) (an apparatus for counting the number of particles on the surface of a Si wafer using laser reflected light). The thus counted number of particles was considered as the amount of insoluble matter that was deposited during rinsing with pure water and adhered to the Si wafer. The results are shown in Table 1.

It is to be noted that in Table 1, MEA is an abbreviation for monoethanolamine, MIPA for isopropanolamine, TETA for triethylenetetramine, MAE for N-methylethanolamine, EAE for N-ethylethanolamine, DEA for N,N-diethanolamine, BDG for diethylene glycol monobutyl ether, DMAC for N,N-dimethylacetamide, NMP for N-methyl-2-pyrrolidone, EC for ethylene carbonate, PC for propylene carbonate, GBR for γ-butyrolactone, DHP for 1,3-dihydroxy-2-propanone, DMSO for dimethyl sulfoxide, OA for oxalic acid, MA for malonic acid, DMPU for dimethylpropylene urea, DMI for 1,3-dimethyl-2-imidazolidinone, EAA is a compound represented by the following formula (1), and DMAA is a compound represented by the following formula (2):

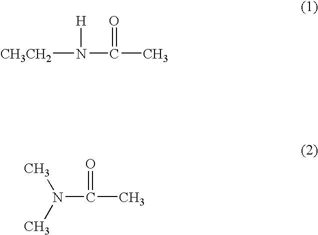

Each of the dehydration condensation reaction product of MEA and OA and the dehydration condensation reaction product of MEA and MA shown in Table 1 was obtained by subjecting all the carboxyl groups of the divalent carboxylic acid to dehydration condensation reaction. Further, all the reaction products used in Examples 1 to 8 and 11 to 15 were equimolar reaction products. That is, each of the reaction products was obtained by mixing components in an equimolar ratio. At this time, the temperature of a reaction liquid was increased due to self-heating, and therefore the reaction liquid was left standing for about 30 minutes to decrease the temperature of the reaction liquid to room temperature before use.

Each of the reaction products was analyzed by GC-MS. As a result, the reaction product of MEA and EC was identified as bis(2-hydroxyethyl)carbamate, the reaction product of MIPA and PC was identified as bis(2-hydroxypropyl)carbamate, the reaction product of MEA and GBR was identified as N-(2-hydroxyethyl)-C-(3-hydroxypropyl)amide, the dehydration condensation reaction product of MEA and OA was identified as N,N′-bis(2-hydroxyethyl)oxamide, the dehydration condensation reaction product of MEA and MA was identified as N,N′-bis(2-hydroxyethyl)malonamide, and the dehydration condensation reaction product of MEA and acetic acid was identified as (2-hydroxyethyl)acetamide.

TABLE 1

| | Composition of | | Non-corrosiveness | |
|---|---|---|---|---|
| | remover liquid | Removing | to | Number of |
| | (wt %) | Performance | Aluminum | Particles |
| Example 1 | Reaction product of | ∘ | ∘ | 35 |
| | MEA and EC:MEA = 50:50 | | | |
| Example 2 | Reaction product of | ∘ | ∘ | 155 |
| | MEA and EC:MEA:DMAC = 5:65:30 | | | |
| Example 3 | Reaction product of | ∘ | ∘ | 91 |
| | MIPA and PC:MIPA = 30:70 | | | |
| Example 4 | Reaction product of | ∘ | ∘ | 42 |
| | MEA and EC:BDG = 50:50 | | | |
| Example 5 | Reaction product of | ∘ | ∘ | 38 |
| | MEA and EC = 100 | | | |
| Example 6 | Reaction product of | ∘ | ∘ | 14 |
| | MEA and GBR:MEA = 10:90 | | | |
| Example 7 | Reaction product of | ∘ | ∘ | 38 |
| | MEA and DHP:MEA = 50:50 | | | |
| Example 8 | Reaction product of MEA and | ∘ | ∘ | 24 |
| | GBR:MEA:NMP:water = 50:5:25:20 | | | |
| Example 9 | Dehydration condensation reaction | ∘ | ∘ | 63 |
| | product of MEA and OA:MEA = 10:90 | | | |
| Example 10 | Dehydration condensation | ∘ | ∘ | 73 |
| | reaction product of MEA | | | |
| | and MA:MEA = 10:90 | | | |
| Example 11 | Dehydration condensation reaction | ∘ | ∘ | 71 |
| | product of MEA and acetic | | | |
| | acid:MEA = 10:90 | | | |
| Example 12 | Reaction product of | ∘ | ∘ | 120 |
| | TETA and GBR:TETA = 80:20 | | | |
| Example 13 | Reaction product of | ∘ | ∘ | 55 |
| | MEA and GBR:MEA = 56:44 | | | |
| Example 14 | Reaction product of | ∘ | ∘ | 347 |
| | MEA and GBR:MEA = 61:39 | | | |
| Example 15 | Reaction product of | ∘ | ∘ | 701 |
| | DEA and GBR:DEA = 67:33 | | | |
| Comparative | MEA:DMSO = 70:30 | x | ∘ | 2033 |
| Example 1 | | | | |
| Comparative | EC:BDG = 50:50 | x | ∘ | 23784 |
| Example 2 | | | | |
| Comparative | MEA = 100 | x | ∘ | 3378 |
| Example 3 | | | | |
| Comparative | DMPU:MEA = 50:50 | x | ∘ | 1598 |
| Example 4 | | | | |
| Comparative | DMI:MEA = 50:50 | x | ∘ | 1761 |
| Example 5 | | | | |
| Comparative | EAA:MEA = 10:90 | x | ∘ | 19933 |
| Example 6 | | | | |
| Comparative | DMAA:MEA = 30:70 | x | ∘ | 2748 |
| Example 7 | | | | |

As can be seen from Table 1, the remover compositions of Examples 1 to 15 each containing the compound (A) exhibited high performance in removing a photoresist, preventing aluminum corrosion, and preventing readhesion of a photoresist. On the other hand, the remover compositions of Comparative Examples 1 to 7 not containing the compound (A) exhibited poor performance in removing a photoresist damaged by ashing and preventing readhesion of a photoresist. Among them, the compound used in Comparative Example 6 had an acid amide structure but did not have an OH group, and the compound used in Comparative Example 7 had no acid amide structure nor OH group, and both were inferior to the remover compositions of Examples 6 and 9 to 11 each having composition corresponding to that of the present invention in photoresist removing performance and prevention of readhesion of a photoresist.

### INDUSTRIAL APPLICABILITY

The photoresist remover composition and the photoresist removing method according to the present invention are suitably used for manufacturing electronic circuits for semiconductor devices or liquid crystal panels.

1. A composition for removing a photoresist comprising at least one compound (A) selected from a group consisting of a compound represented by the following general formula (I), a compound represented by the following general formula (II), a compound represented by the following general formula (III), and a compound represented by the following general formula (IV): 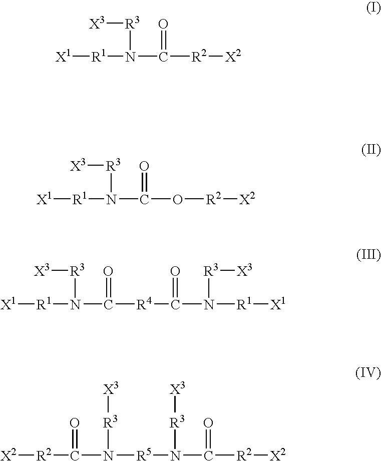
wherein formulas (I) to (IV), R¹ and R³ each independently represent a direct bond, or a linear or branched divalent hydrocarbon group having 1 to 5 carbon atoms, R² represents a linear or branched divalent hydrocarbon group having 1 to 5 carbon atoms, X¹, X², and X³ each independently represent a hydrogen atom, an OH group, or an alkyl group having 1 to 5 carbon atoms, and at least one of X¹, X², and X³ in each of the formulas (I) to (IV) is an OH group; wherein formulas (III) and (IV), the plurality of R¹s, R²s, and R³s, and the plurality of X¹s, X²s, and X³s are the same or different; wherein formula (III), R⁴ represents a direct bond, or a linear or branched divalent hydrocarbon group having 1 to 5 carbon atoms; and wherein formula (IV), R⁵ represents a divalent organic group.

2. The composition according to claim 1, wherein the compound (A) is at least one compound selected from a group consisting of reaction products of ethylene carbonate and primary or secondary organic amines, reaction products of propylene carbonate and primary or secondary organic amines, reaction products of γ-butyrolactone and primary or secondary organic amines, reaction products of 1,3-dihydroxy-2-propanone and primary or secondary organic amines, and dehydration condensation reaction products of mono- or dicarboxylic acids and primary or secondary organic amines.

3. The composition according to claim 2, wherein the compound (A) is at least one compound selected from a group consisting of bis(2-hydroxyethyl)carbamate, bis(2-hydroxypropyl)carbamate, N-(2-hydroxyethyl)-C-(3-hydroxypropyl)amide, N,N′-bis(2-hydroxyethyl)oxamide, N,N′-bis(2-hydroxyethyl)malonamide, (2-hydroxyethyl)acetamide, N-(2-hydroxyethyl)-N-methyl-C-(3-hydroxypropyl)amide, N-(2-hydroxyethyl)-N-ethyl-C-(3-hydroxypropyl)amide, and N,N-bis(2-hydroxyethyl)-C-(3-hydroxypropyl)amide.

4. The composition according to claim 1, wherein at least X¹ and X² of the compound (A) are OH groups.

5. The composition according to claim 1, further comprising an organic amine (B).

6. The composition according to claim 1, further comprising a water-soluble organic solvent (C).

7. The composition according to claim 1, further comprising water (D).

8. The composition according to claim 1, wherein the amount of the compound (A) is from 5 to 100 wt %.

9. A method for removing a photoresist comprising the steps of:
(1) preparing the composition according to any one of claims 1 to 8; and
(2) immersing an object having a photoresist to be removed in the composition.

10. The method according to claim 9, further comprising the step of rinsing the object with water after the step (2).

11. The method according to claim 9, wherein the photoresist is a positive-type photoresist.
